(19) United States
(12) Patent Application Publication
(10) Pub. No.: US 2012/0313077 A1
(43) Pub. Date: Dec. 13, 2012

(54) HIGH EMISSION POWER AND LOW EFFICIENCY DROOP SEMIPOLAR BLUE LIGHT EMITTING DIODES

(75) Inventors: Shuji Nakamura, Santa Barbara, CA (US); Steven P. DenBaars, Goleta, CA (US); Daniel F. Feezell, Santa Barbara, CA (US); Chih-Chien Pan, Goleta, CA (US); Yuji Zhao, Goleta, CA (US); Shinichi Tanaka, Santa Barbara, CA (US)

(73) Assignee: The Regents of the University of California, Oakland, CA (US)

(21) Appl. No.: 13/493,483

(22) Filed: Jun. 11, 2012

Related U.S. Application Data
(60) Provisional application No. 61/495,840, filed on Jun. 10, 2011.

(51) Int. Cl. H01L 33/04; H01L 33/32

(52) U.S. Cl. 257/13; 438/47; 257/E33.008

(57) ABSTRACT

High emission power and low efficiency droop semipolar blue light emitting diodes (LEDs).

### CROSS REFERENCE TO RELATED APPLICATION

This application claims the benefit under 35 U.S.C. Section 119(e) of co-pending and commonly-assigned U.S. Provisional Patent Application Ser. No. 61/495,840, filed on Jun. 10, 2011, by Shuji Nakamura, Steven P. DenBaars, Daniel F. Feezell, Chih-Chien Pan, Yuji Zhao and Shinichi Tanaka, and entitled “HIGH EMISSION POWER AND LOW EFFICIENCY DROOP SEMIPOLAR {20-2-1} BLUE LIGHT EMITTING DIODES,” attorney's docket number 30794.416-US-P1 (UC 2011-833-1), which application is incorporated by reference herein.

This application is related to co-pending and commonly-assigned U.S. Utility patent application Ser. No. ______, filed on Jun. 10, 2010, by Shuji Nakamura, Steven P. DenBaars, Shinichi Tanaka, Daniel F. Feezell, Yuji Zhao and Chih-Chien Pan, and entitled “LOW DROOP LIGHT EMITTING DIODE STRUCTURE ON GALLIUM NITRIDE SEMIPOLAR SUBSTRATES,” attorney's docket number 30794.415-US-U1 (UC 2011-832-1), which application claims the benefit under 35 U.S.C. Section 119(e) of U.S. Provisional Patent Application Ser. No. 61/495,829, filed on Jun. 10, 2010, by Shuji Nakamura, Steven P. DenBaars, Shinichi Tanaka, Daniel F. Feezell, Yuji Zhao and Chih-Chien Pan, and entitled “LOW DROOP LIGHT EMITTING DIODE STRUCTURE ON GALLIUM NITRIDE SEMIPOLAR {20-2-1} SUBSTRATES,” attorney's docket number 30794.415-US-P1 (UC 2011-832-1);

U.S. Utility application Ser. No. 12/284,449 filed on Oct. 28, 2011, by Matthew T. Hardy, Steven P. DenBaars, James S. Speck, and Shuji Nakamura, entitled “STRAIN COMPENSATED SHORT-PERIOD SUPERLATTICES ON SEMIPOLAR GAN FOR DEFECT REDUCTION AND STRESS ENGINEERING,” attorney's docket number 30794.396-US-U1 (2011-203), which application claims the benefit under 35 U.S.C. Section 119(e) of co-pending and commonly-assigned U.S. Provisional Application Ser. No. 61/408,280 filed on Oct. 29, 2010, by Matthew T. Hardy, Steven P. DenBaars, James S. Speck, and Shuji Nakamura, entitled “STRAIN COMPENSATED SHORT-PERIOD SUPERLATTICES ON SEMIPOLAR GAN FOR DEFECT REDUCTION AND STRESS ENGINEERING,” attorney's docket number 30794.396-US-P1 (2011-203);

U.S. Utility patent application Ser. No. 12/908,793, entitled “LED PACKAGING METHOD WITH HIGH LIGHT EXTRACTION AND HEAT DISSIPATION USING A TRANSPARENT VERTICAL STAND STRUCTURE,” filed on Oct. 20, 2010, by Chih Chien Pan, Jun Seok Ha, Steven P. DenBaars, Shuji Nakamura, and Junichi Sonoda, attorney's docket number 30794.335-US-P1, which application claims the benefit under 35 U.S.C. Section 119(e) of U.S. Provisional Patent Application Ser. No. 61/258,056, entitled “LED PACKAGING METHOD WITH HIGH LIGHT EXTRACTION AND HEAT DISSIPATION USING A TRANSPARENT VERTICAL STAND STRUCTURE,” filed on Nov. 4, 2009, by Chih Chien Pan, Jun Seok Ha, Steven P. DenBaars, Shuji Nakamura, and Junichi Sonoda, attorney's docket number 30794.335-US-P1;

all of which applications are incorporated by reference herein.

### BACKGROUND OF THE INVENTION

1. Field of the Invention

The invention is related generally to the field of electronic and optoelectronic devices, and more particularly, to high emission power and low efficiency droop semipolar (e.g., {20-1-1}) blue light emitting diodes (LEDs).

2. Description of the Related Art

(Note: This application references a number of different publications as indicated throughout the specification by one or more reference numbers within brackets, e.g., [X]. A list of these different publications ordered according to these reference numbers can be found below in the section entitled “References.” Each of these publications is incorporated by reference herein.)

InGaN/GaN based high-brightness light-emitting diodes (LEDs) have attracted much attention because of their applications in mobile phones, back lighting, and general illumination. However, LEDs grown on the c-plane of a wurtzite crystal suffer from the Quantum Confined Stark Effect (QCSE) due to the large polarization-related electric fields that cause band bending in the active region resulting in lower internal quantum efficiencies because of the spatial separation of the electron and hole wave functions. Also, the internal quantum efficiency is further reduced in the higher current density region due to Auger non-radiative recombination, which is proportional to the third power of carrier concentration.

Semipolar (20-2-1) GaN-based devices are promising for high emission efficiency LEDs because they exhibit very little QCSE, hence increasing the radiative recombination rate due to an increase in the electron-hole wave function overlap. In addition, semipolar (20-2-1) blue LEDs also exhibit narrower Full Width at Half Maximum (FWHM) as compared to polar (c-plane) blue LEDs at different current densities, which could contribute to relatively high internal quantum efficiency because of reducing the alloy-assisted Auger non-radiative recombination.

Thus, there is a need in the art for improved methods for providing high emission power and low efficiency droop in LEDs. The present invention satisfies this need. Specifically, the present invention describes a high emission power and low efficiency droop semipolar {20-1-1} blue LED.

### SUMMARY OF THE INVENTION

To overcome the limitations in the prior art described above, and to overcome other limitations that will become apparent upon reading and understanding the present specification, the present invention demonstrates that nitride based blue LEDs having a small chip size (˜0.1 mm²) grown on a semipolar (20-2-1) plane, which are packaged with a novel, transparent, vertical geometry ZnO bar, achieve external quantum efficiency (EQE) levels of 52.56%, 50.67%, 48.44%, and 45.35%, and efficiency roll-overs (EQEₚₑₐₖ=52.91% @ 10 A/cm²) of only 0.7%, 4.25%, 8.46%, and 14.3%, at current densities of 35, 50, 100, and 200 A/cm² under pulsed operation (1% duty cycle), respectively. Under DC conditions, the (20-2-1) blue LED having a small chip size also can achieve EQE levels of 50.73%, 49.31%, 46.02%, and 41.4%, and efficiency roll-overs (EQEₚₑₐₖ=51.6% @ 20 A/cm²) of only 1.69%, 4.44%, 10.81%, and 19.79%, at current densities of 35, 50, 100, and 200 A/cm², respectively.

The present invention also discloses a III-nitride based light emitting diode (LED) having a peak emission at a blue emission wavelength, wherein the LED is grown on a semipolar Gallium Nitride (GaN) substrate, and the peak emission at the blue emission wavelength has a spectral width of less than 17 nanometers at a current density of at least 35 Amps per centimeter square (A/cm²).

The LED can be grown on a semipolar (20-2-1) or (20-21) GaN substrate, for example.

The blue emission wavelength can be in a range of 430 -470 nm.

An efficiency droop of the LED can be less than 1% at the current density of at least 35 A/cm², less than 5% at the current density of at least 50 A/cm², less than 10% at the current density of at least 100 A/cm², and/or less than 15% at the current density of at least 200 A/cm².

The device can further comprise an n-type superlattice (n-SL), e.g., III-nitride superlattice (SL) on or above the GaN substrate; a III-nitride active region, on or above the n-SL, comprising one or more indium containing quantum wells (QWs) with barriers, the quantum wells having a QW number, a QW composition, and a QW thickness, the barriers having a barrier composition, barrier thickness, and barrier doping; and a p-type III-nitride superlattice (p-SL) on or above the active region. The n-SL can comprise a number of periods, an SL doping, an SL composition, and layers each having a layer thickness, and the QW number, the QW composition, the QW thickness, the barrier composition, the barrier thickness, the barrier doping, the number of periods, the SL doping, the SL composition, the layer thickness can be such that the peak emission is at the blue emission wavelength, and the peak emission at the blue emission wavelength has a spectral width of less than 17 nanometers when the LED is driven with a current density of at least 35 Amps per centimeter square (A/cm²).

The n-SL can comprise alternating InGaN and GaN layers on or above an n-type GaN layer, wherein the n-type GaN layer is on or above a semi-polar plane of the substrate.

An active region, comprising InGaN multi quantum wells (MQWs) with GaN barriers, can be on or above the n-SL.

A p-type SL (p-SL), comprising alternating AlGaN and GaN layers, can be on or above the active region.

The substrate can be a semi-polar GaN substrate having a roughened backside wherein the roughened backside extracts light from the light emitting device, and

The device can further comprise a p-type GaN layer on or above the p-SL, a p-type transparent conductive layer on or above the p-type GaN layer, a p-type pad on or above the p-type transparent conductive layer; an n-type contact to the n-type GaN layer; a Zinc Oxide (ZnO) submount attached to the roughened backside of the semipolar GaN substrate; a header attached to an end of the ZnO submount; and an encapsulant encapsulating the LED. An active area of the LED device structure can be 0.1 mm² or less.

The present invention further discloses a III-nitride based light emitting diode (LED) having a peak emission at a blue emission wavelength, wherein the LED is grown on a bulk semipolar or nonpolar Gallium Nitride (GaN) substrate, and an efficiency droop is lower than a III-nitride based LED grown on a polar GaN substrate having a similar Indium (In) composition and operating at a similar current density. A full width at half maximum (FWHM) of an emission spectrum of the LED can be lower than that of a III-nitride based LED grown on a polar GaN substrate having a similar indium composition and operating at a similar current density.

### BRIEF DESCRIPTION OF THE DRAWINGS

Referring now to the drawings in which like reference numbers represent corresponding parts throughout:

FIG. 1(a) is a cross-sectional schematic illustrating the epi structure of a semipolar {20-2-1} LED grown on a semipolar {20-2-1} GaN substrate by MOCVD, according to one embodiment of the present invention.

FIG. 1(b) is a cross-sectional schematic illustrating the structure of FIG. 1(a) processed into a device.

FIG. 1(c) illustrates a Zinc Oxide (ZnO) submount attached to the semipolar GaN substrate of the LED.

FIG. 2 is a flowchart illustrating a method of fabricating an optoelectronic device according to an embodiment of the present invention.

FIG. 3 is a graph that shows the light output power (LOP) (mW) and external quantum efficiency (EQE) (%) of the semipolar (20-2-1) LED at different current densities up to 200 A/cm².

FIG. 4 is a graph that shows the LOP (mW) and EQE (%) of both the polar c-plane (0001) LED and the semipolar (20-2-1) LED at different pulsed (1% duty cycle) current densities up to 200 A/cm².

FIG. 5 shows the full width at half maximum (FWHM) for both polar (c-plane) and semipolar (20-2-1) GaN-based devices at different current densities.

FIG. 6 is a graph showing emission wavelength (nm) as a function of current density (A/cm²) and FWHM (nm) as a function of current density for a blue light emitting diode having a structure as shown in FIG. 1(b).

FIG. 7(a) is a graph plotting Electroluminescence (EL) as a function of wavelength for a (20-2-1) LED having a peak emission wavelength at 515 nm and a FWHM of 25 nm and for a (20-2-1) LED having a peak emission wavelength at 516 nm and a FWHM of 40 nm.

FIG. 7(b) is a graph plotting FWHM (nm) as a function of wavelength for LEDs having a peak emission wavelength in a green wavelength range, for a c-plane LED, a (11-22) LED, a (20-21) LED, and a (20-2-1) LED.

FIG. 8(a) is a graph plotting EL wavelength (nm) as a function of driving current for a c-plane LED, a (11-22) LED, a (20-21) LED, and a (20-2-1) LED, wherein the LED chip size is ˜0.01 mm².

FIG. 8(b) is a graph plotting FWHM (nm) as a function of driving current for LEDs having a peak emission wavelength in a green wavelength range (a (11-22) LED, a (20-21) LED, and a (20-2-1) LED.

FIG. 9(a) is a graph plotting EL wavelength (nm) and FWHM as a function of driving current, and FIG. 9(b) is a graph plotting EL intensity as a function of wavelength for various driving currents, for LEDs having a peak emission wavelength in a green wavelength range.

FIG. 10 is a diagram that illustrates the Auger recombination process for isotropically-strained structures (c-plane) and anisotropically-strained structures (semipolar).

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses high emission power and low efficiency droop semipolar (20-2-1) blue LEDs. These LEDs can be used in a variety of products, including flashlights, televisions, streetlights, automotive lighting, and general illumination (both indoor and outdoor).

Due to the droop reduction observed in semipolar (20-2-1) blue LEDs, they offer benefits compared to commercial c-plane LEDs grown on patterned sapphire substrates or silicon carbide substrates, especially in high emission power and extreme low efficiency-rollover devices.

Technical Description

The peak quantum efficiency of polar (c-plane) InGaN/GaN multiple quantum well (MQW) LEDs occurs at very low current densities, typically <10 A/cm², and gradually decreases with further increasing injection current, which is the critical restriction for high power LED applications. This phenomenon, known as “efficiency droop,” becomes more severe while the peak emission wavelength of LEDs further increases from the UV spectral range toward the blue and green spectral range. Many theories regarding its origins have been reported, such as Auger recombination, electron leakage, carrier injection efficiency, polarization fields, and band filling of localized states.

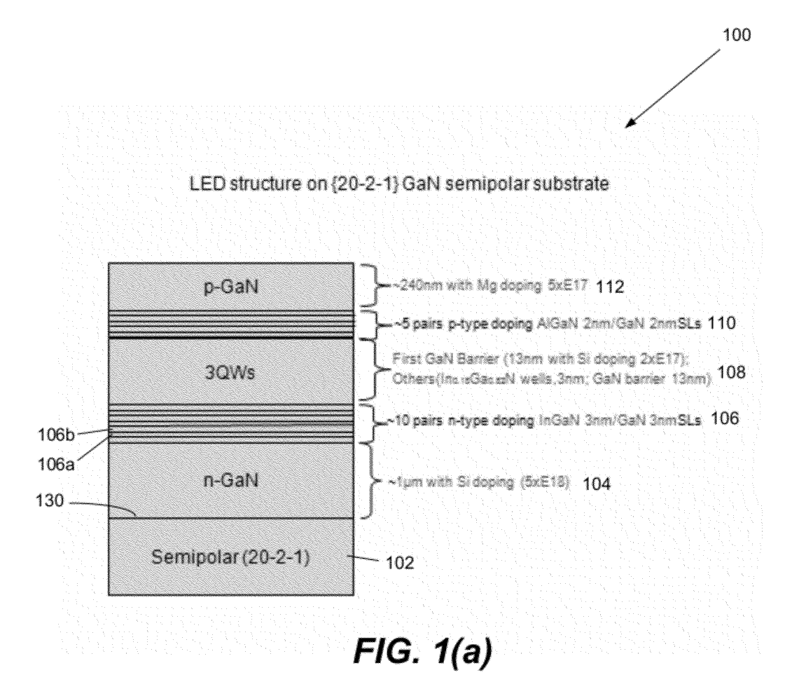

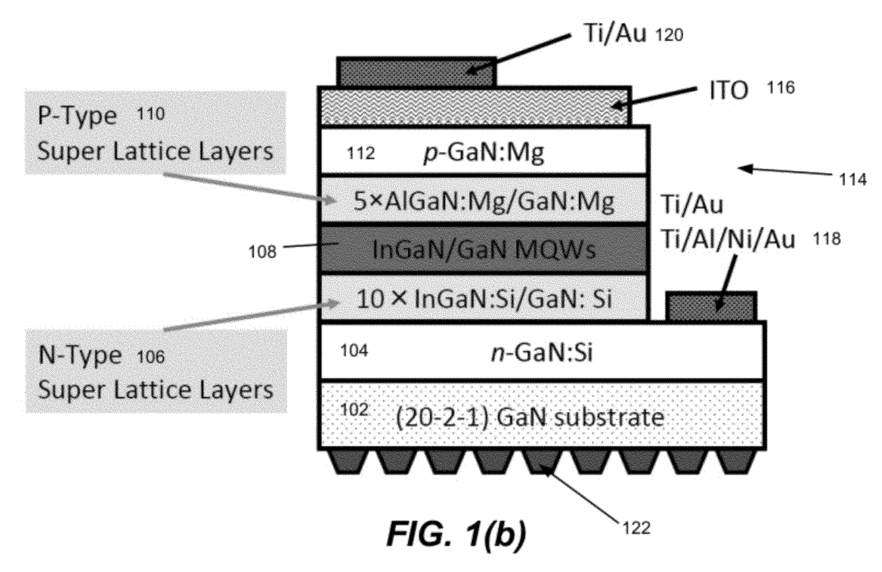

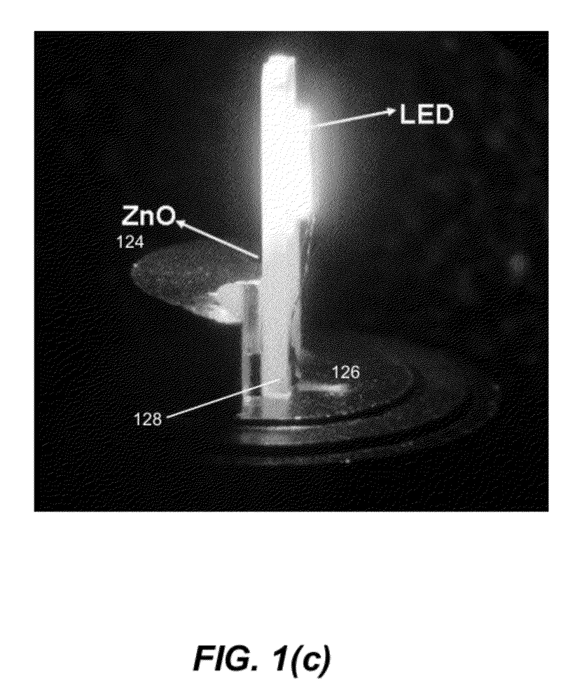

For the exploration of efficiency droop in InGaN blue LEDs, the nonradiative Auger recombination or carrier leakage due to polarization-related electric fields has been implicated as the cause of efficiency droop. By using semipolar bulk GaN as a substrate to grow InGaN blue LEDs, the polarization-induced QCSE can be reduced in the active region, which results in higher a radiative recombination rate, which increases the overall emission efficiency (external quantum efficiency) of the LEDs. Additionally, more uniform distribution of electrons and holes in the active region of semipolar LEDs, which results in reducing the carrier concentration in the quantum wells, can reduce noradiative Auger recombination which is another possible mechanism for causing efficiency droops. FIG. 1(a) illustrates the epi structure 100 of a blue LED grown on a GaN semipolar {20-2-1} substrate 102 by MOCVD according to one embodiment of the present invention. This device structure is comprised of a 1-μm-thick undoped GaN layer 104 with an electron concentration of 5×10¹⁸ cm⁻³, followed by 10 pairs of an n-type doped In_{0.01}Ga_{0.99}N/GaN (3/3 nm) superlattice (SL) 106. Then, a three-period InGaN/GaN MQW active region 108 is grown, comprised of 3.0-nm-thick In_{0.18}Ga_{0.82}N wells and 13-nm-thick GaN barriers (first GaN barrier with 2×10¹⁷ cm⁻³ Si doping). On top of the active region are 5 pairs of a p-Al_{0.2}Ga_{0.8}N/GaN (2/2 nm) SL 110 acting as an electron blocking layer (EBL) and a 0.2-μm-thick p-type GaN capping layer 112 with a hole concentration of 5×10¹⁷ cm⁻³.

FIG. 1(b) illustrates the device structure 100 processed into a device (e.g., LED), illustrating a mesa 114 and a p-type transparent conductive layer (e.g., indium tin oxide (ITO) transparent p-contact 116) on or above the p-type GaN layer 112. Ti/Al/Au based n-contacts 118 and Ti/Au p-pads 120 are deposited on or above, or make contact to, the n-GaN layer 104 and the ITO transparent p-contact 116, respectively. Surface roughening 122 of the GaN substrate 102 is also shown, wherein the roughened backside 122 has features having a dimension to extract (e.g., scatter, diffract) light emitted by the active region 108 from the LED.

FIG. 1(c) illustrates a Zinc Oxide (ZnO) submount 124 attached to the roughened backside 122 of the semipolar GaN substrate 102 and a header 126 attached to an end 128 126 of the ZnO submount 124. The LED can further comprise an encapsulant encapsulating the LED, wherein an active area of the LED is 0.1 mm² or less, for example.

Process Steps

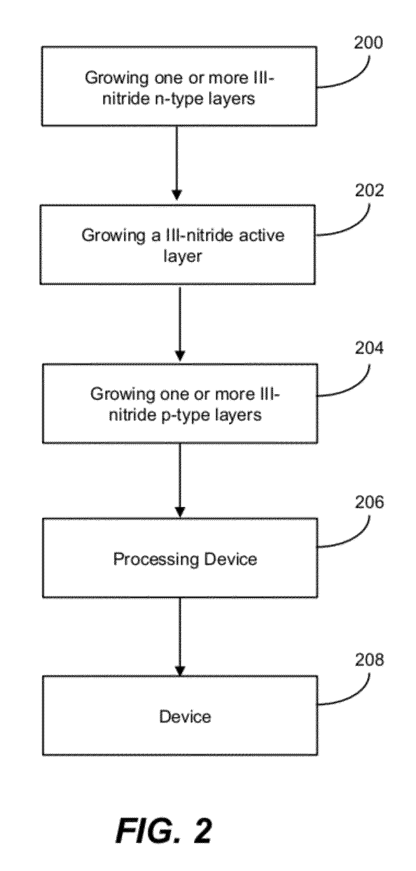

FIG.2 illustrates a method of fabricating a light emitting device, comprising growing a III-nitride based light emitting diode (LED) on a (e.g., bulk) semipolar III-nitride or Gallium Nitride (GaN) substrate, wherein the LED has a peak emission at a blue emission wavelength, and the peak emission at the blue emission wavelength (e.g., 430 or 470 nm or 430-470 nm) has a spectral width of less than 17 nanometers when the LED is driven with a current density of at least 35 Amps per centimeter square (A/cm²). Growing the LED can comprise the following steps.

Block 200 represents growing one or more first III-nitride layers (e.g., buffer layer) and/or n-type III-nitride layers 104, 106 on or above semipolar Group-III nitride, e.g., on or above a semipolar Group-III nitride (e.g., bulk) substrate 102 or on or above a semi-polar plane 130 of the substrate 102. The semipolar Group-III nitride can be semipolar GaN. The semipolar group-III nitride can be a semipolar (20-2-1) or (20-21) GaN substrate 102. The first or buffer layer can comprise one of the n-type layers 104.

The n-type layers can comprise an n-SL 106.

The n-SL 106 can be on or above the one or more n-type layers 104, or on or above the first layer or buffer layer.

The n-SL can comprise SL layers 106a, 106b, e.g., one or more indium (In) containing layers and gallium (Ga) containing layers, or alternating first and second III-nitride layers 106a, 106b having different III-nitride composition (e.g., InGaN and GaN layers).

The n-SL 106 can comprise a number of periods (e.g., at least 5, or at least 10), an

SL doping, an SL composition, and layers 106a, 106b each having a layer thickness. The first and second III-nitride layers 106a, 106b can comprise strain compensated layers that are lattice matched to the first or buffer layer 104 and can have a thickness that is below their critical thickness for relaxation (e.g., less than 5 nm). The strain compensated layers can be for defect reduction, strain relaxation, and/or stress engineering in the device 100 and/or active region 108. A number of periods of the n-SL 106 can be such that the active region 108 grown in Block 202 is separated from the first layer 104 by at least 500 nanometers.

Further information on strain compensated SL layers can be found in U.S. Utility application Ser. No. 12/284,449 filed on Oct. 28, 2011, by Matthew T. Hardy, Steven P. DenBaars, James S. Speck, and Shuji Nakamura, entitled “STRAIN COMPENSATED SHORT-PERIOD SUPERLATTICES ON SEMIPOLAR GAN FOR DEFECT REDUCTION AND STRESS ENGINEERING,” attorney's docket number 30794.396-US-U1 (2011-203), which application is incorporated by reference herein.

Block 202 represents growing an active region or one or more active layer(s) 108 on or above the n-SL. The active layers 108 can emit light (or electromagnetic radiation) having a peak intensity at a wavelength in a blue or green wavelength range, or longer (e.g., red or yellow light), or a peak intensity at a wavelength of 500 nm or longer. However, the present invention is not limited to devices 100 emitting at particular wavelengths, and the devices 100 can emit at other wavelengths. For example, the present invention is applicable to ultraviolet light emitting devices 100.

The light emitting active layer(s) 108 can comprise III-nitride layers such as Indium (In) containing III-nitride layers or such as InGaN layers. For example, the Indium containing layers can comprise one or more QWs (having a QW number, a QW composition, and a QW thickness), and QW barriers having a barrier composition, barrier thickness, and barrier doping. For example, the indium containing layers can comprise at least two or three InGaN QWs with, e.g., GaN barriers. The InGaN QWs can have an Indium composition of at least 7%, at least 10%, at least 18%, or at least 30%, and a thickness or well width of 3 nanometers or more, e.g., 5 nm, at least 5 nm, or at least 9 nm. However, the quantum well thickness can also be less than 3 nm, although it is typically above 2 nm thickness.

Block 204 represents growing one or more III-nitride p-type III-nitride layers (e.g., a p-SL comprising p-SL layers) on or above the active region. The p-SL can comprise alternating AlGaN and GaN layers (AlGaN/GaN layers), for example. The p-SL can comprise an AlGaN electron blocking layer.

Layers 104, 106, 108, 110, and 112 can form a p-n junction. Generally, the preferred embodiment of the present invention comprises an LED grown on a GaN semipolar {20-2-1} substrate in which the structure incorporates an n-type SL below the active layer, a MQW active region, and a p-type SL layer above the MQW. The MQW active region should typically comprise two or more QWs, and more preferably, at least three QWs.

The semipolar plane, QW number, the QW composition (e.g., In composition), the QW thickness, the barrier composition, the barrier thickness, the barrier doping, the number of periods of the SL, the SL doping, the SL composition, and the layer thickness can be such that the light emitting device has a peak emission at the desired emission wavelength (e.g., a blue emission wavelength or longer), with the desired droop (e.g., the droop can be 15 percent or less when the device is driven at a current density of at least 35 A/cm²).

Block 206 represents processing the device structure.

The semipolar {20-2-1} blue LEDs can be further processed as follows.

1. Subsequently, 300×500 μm² diode mesas can be isolated by chlorine-based reactive ion etching (RIE).

2. An 250 nm indium-tin-oxide (ITO) layer can be used as the transparent p-contact and a stack of (10/100/10/100 nm) Ti/Al/Ni/Au layers can be deposited as the n-GaN contact.

3. A 200/500 nm thick Ti/Au metal stack can be deposited on the ITO layer and the n-GaN contact to serve as p-side and n-side wire bond pads.

Block 208 represents the end result, a device such as a III-nitride based light emitting diode (LED) having a peak emission at a blue emission wavelength, wherein the LED is grown on a (e.g., bulk) semipolar Gallium Nitride (GaN) substrate, and the peak emission at the blue emission wavelength has a spectral width of less than 17 nanometers when the LED is driven with a current density of at least 35 Amps per centimeter square (A/cm²). The light emitting device can have a light output power that is at least 100 mW or at least 50 mW. The device can comprise a III-nitride based LED grown on a nonpolar or semipolar (e.g., 20-2-1) substrate, wherein an efficiency droop of the LED can be 1% or less at the current density of 35 A/cm², 5% or less at the current density of 50 A/cm², 10% or less at the current density of 100 A/cm², and/or 15% or less at the current density of 200 A/cm².

The light emitting device can comprise a III-nitride based semipolar or nonpolar LED operating at more than 100/A cm².

The light emitting device can comprise a III-nitride LED grown on a semipolar (e.g., 20-2-1) or nonpolar substrate (e.g., GaN), wherein an efficiency droop can be lower than a III-nitride based LED grown on a polar (e.g., GaN) substrate having a similar Indium (In) composition and operating at a similar current density.

For comparison, a reference polar (c-plane) blue LED was grown with the same structure and wavelength, and then compared to the semipolar (20-2-1) blue LED, except having different numbers of n-type and p-type SLs.

The light emitting device can comprise a nitride based LED grown on a semipolar or nonpolar substrate (e.g., GaN), wherein a FWHM of an emission spectrum of the LED can be lower than that of a III-nitride based LED grown on a polar (e.g., GaN) substrate having a similar indium composition and operating at a similar current density.

The present invention further discloses a light emitting device, comprising a nitride based LED in which anisotropic strain is intentionally added in order to reduce efficiency droop. The LED can be grown on a c-plane, semipolar (e.g., 20-2-1) or nonpolar GaN substrate, or on a c-plane sapphire substrate. The anisotropic strain can be added to light emitting layers of the device. The anisotropic strain can reduce Auger recombination in the device.

Characterization

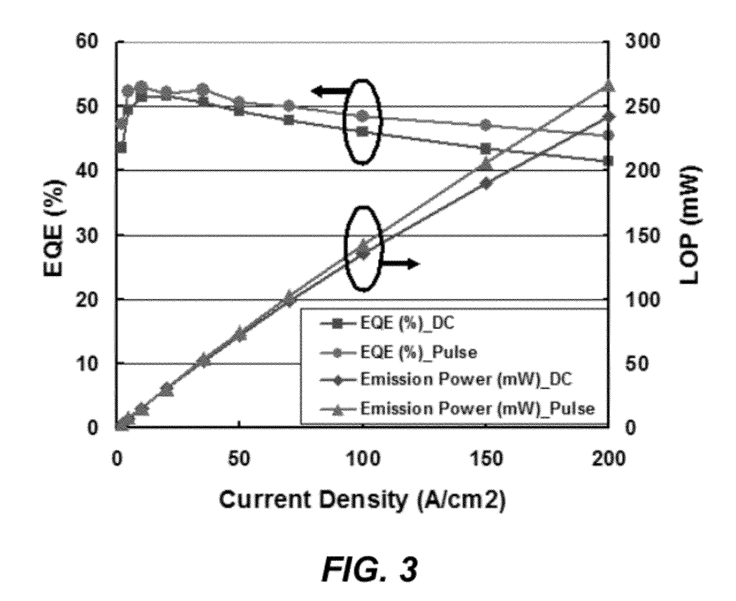

Encapsulated devices were tested in both DC and pulsed mode with a 1 KHz frequency and a 1% duty cycle to prevent self- heating effects. The tests were done at room temperature (RT) with forward currents up to 200 mA. FIG. 3 is a graph that shows the light output power (LOP) (mW) and external quantum efficiency (EQE) (%) of the semipolar (20-2-1) LED at different current densities up to 200 A/cm². The device has the structure and packaging shown in FIGS. 1(a)-(c).

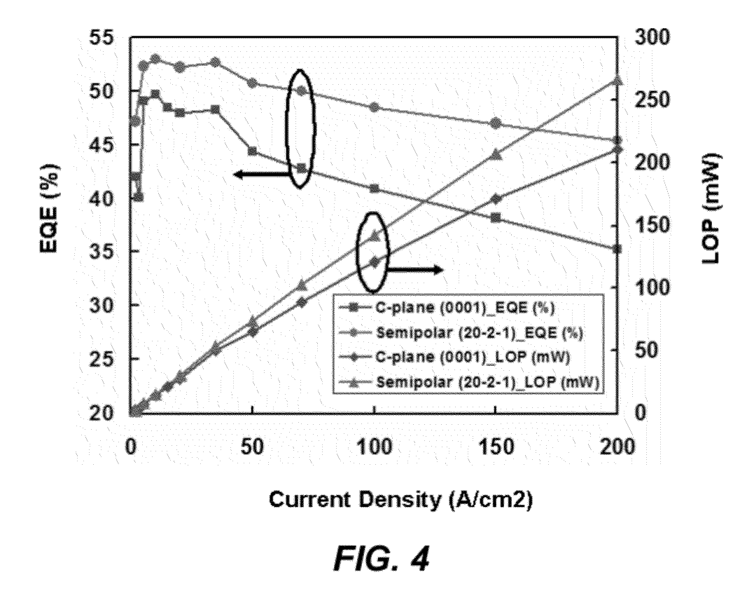

In order to illustrate the advantages of achieving high emission power and low efficiency droop using semipolar (20-2-1) as a bulk GaN substrate, FIG. 4 is a graph that shows the LOP (mW) and EQE (%) of both the polar c-plane (0001) LED and the semipolar (20-2-1) LED at different pulsed (1% duty cycle) current densities up to 200 A/cm², wherein the device has the structure and packaging shown in FIGS. 1(a)-(c).

The corresponding EQE numbers and efficiency droop at different current densities are also shown in Table 1 below.

| | | 35 | 50 | 100 | 200 |
|---|---|---|---|---|---|
| | | (A/cm2) | (A/cm2) | (A/cm2) | (A/cm2) |
| C-plane (0001) | EQE (%) | 48.25 | 44.36 | 40.9 | 35.3 |
| | Efficiency | 2.78 | 10.62 | 17.59 | 28.87 |
| | Droops (%) | | | | |
| Semipolar (20-2-1) | EQE (%) | 52.56 | 50.67 | 48.44 | 45.35 |
| | Efficiency | 0.7 | 4.25 | 8.46 | 14.3 |
| | Droops (%) | | | | |

As can be seen in Table 1, by growing LEDs on the semipolar (20-2-1) plane, the efficiency droop as compared to polar (c-plane) LEDs can be improved from 2.78% to 0.7%, 10.62% to 4.25%, 17.59% to 8.46%, and 28.87% to 14.3% at current densities of 35, 50, 100, 200 A/cm², respectively.

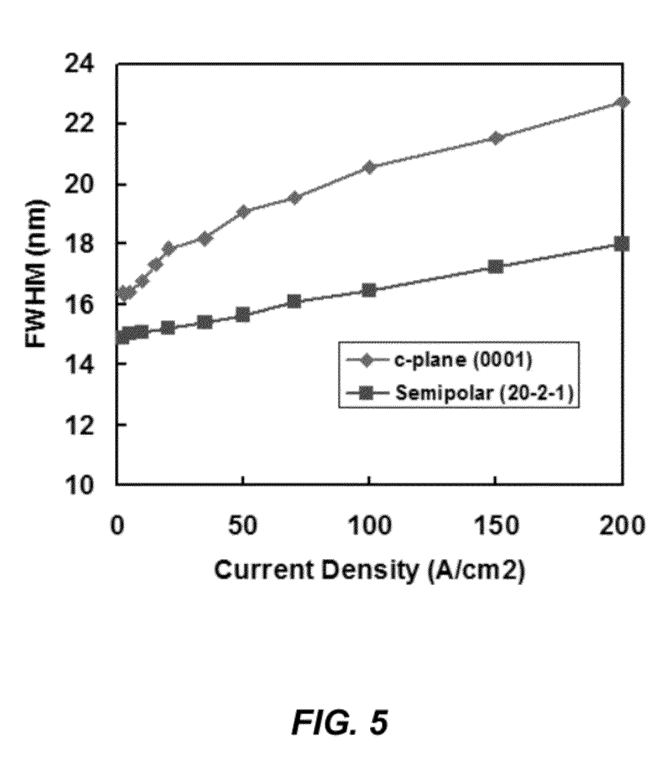

This large improvement in overall efficiency performance by growing LEDs on the semipolar (20-2-1) plane could be explained by a reduction in alloy-assisted non-radiative Auger recombination. FIG. 5 shows the full width at half maximum (FWHM) for both polar (c-plane) and semipolar (20-2-1) GaN-based devices at different current densities.

For the semipolar blue LED, the observed FWHM is narrower than that of a polar (c-plane) LED. One potential explanation for the reduced FWHM is that the InGaN composition in the QWs is more uniform on semipolar (20-2-1). Experiments are currently in progress to examine the origin of the narrower FWHM on semipolar (20-2-1). If more uniform QW layers do indeed exist, alloy scattering, which can assist Auger recombination processes, is expected to be reduced in the semipolar LED.

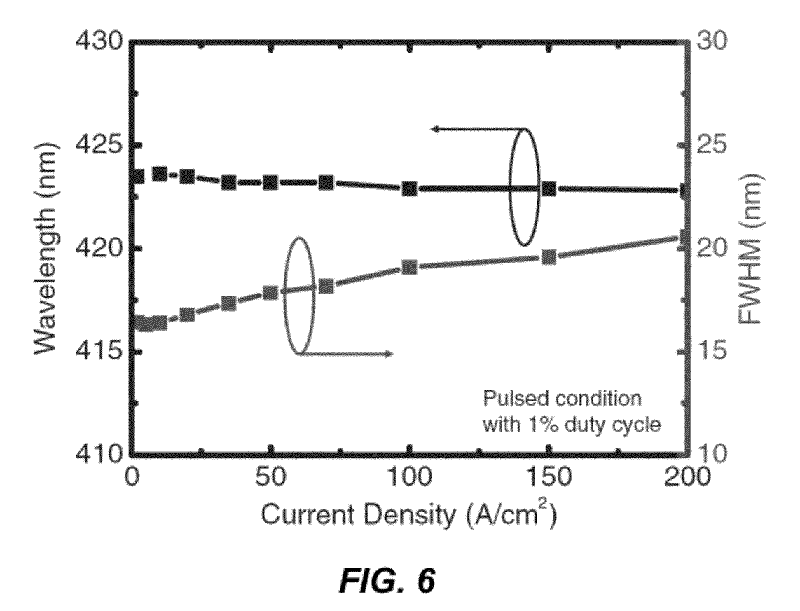

FIG. 6 is a graph showing emission wavelength (nm) vs. current density (A/cm²) and FWHM (nm) vs. current density for a blue light emitting diode having a structure as shown in FIG. 1(b) and packaged as shown in FIG. 1(c).

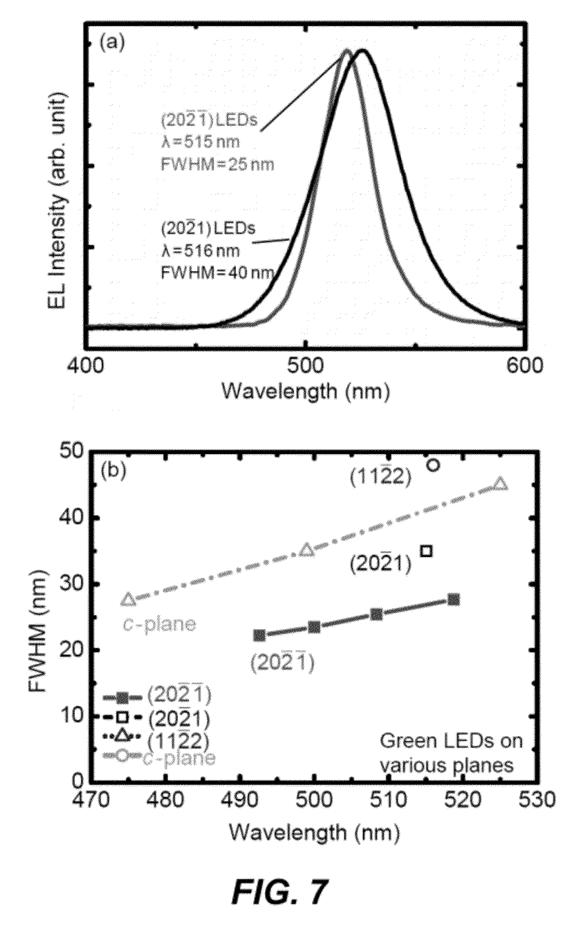

FIG. 7(a) is a graph plotting Electroluminescence (EL) as a function of wavelength for a (20-2-1) LED having a peak emission wavelength at 515 nm and a FWHM of 25 nm and for a (20-2-1) LED having a peak emission wavelength at 516 nm and a FWHM of 40 nm.

FIG. 7(b) is a graph plotting FWHM (nm) as a function of wavelength for LEDs having a peak emission wavelength in a green wavelength range, for a c-plane LED, a (11-22) LED, a (20-21) LED, and a (20-2-1) LED.

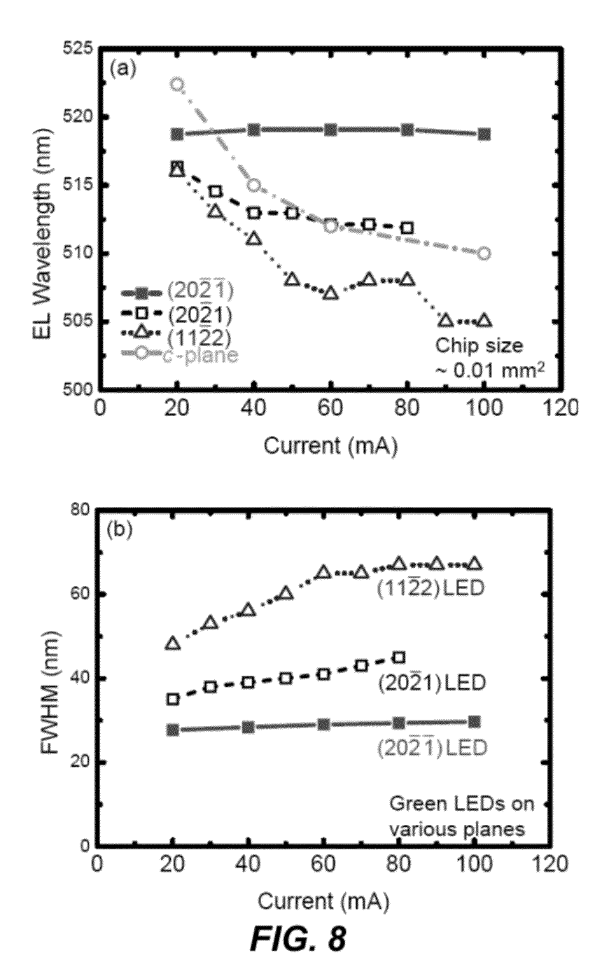

FIG. 8(a) is a graph plotting EL wavelength (nm) as a function of driving current for a c-plane LED, a (11-22) LED, a (20-21) LED, and a (20-2-1) LED, wherein the LED chip size is ˜0.01 mm².

FIG. 8(b) is a graph plotting FWHM (nm) as a function of driving current for LEDs having a peak emission wavelength in a green wavelength range for a (11-22) LED, a (20-21) LED, and a (20-2-1) LED.

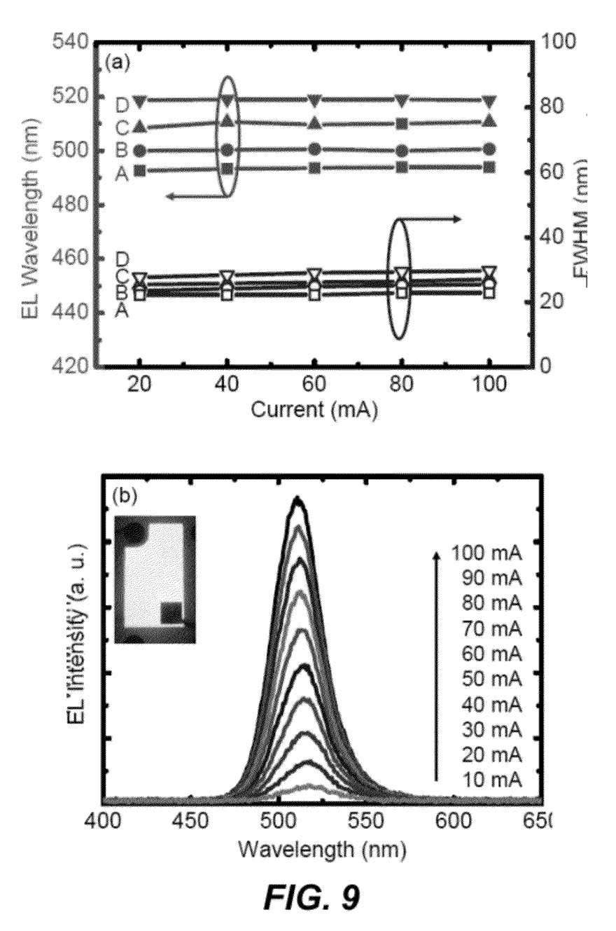

FIG. 9(a) is a graph plotting EL wavelength (nm) and FWHM as a function of driving current, and FIG. 9(b) is a graph plotting EL intensity as a function of wavelength for various driving currents, for LEDs having a peak emission wavelength in a green wavelength range (the inset of FIG. 9(b) shows the top surface of the processed LED structure).

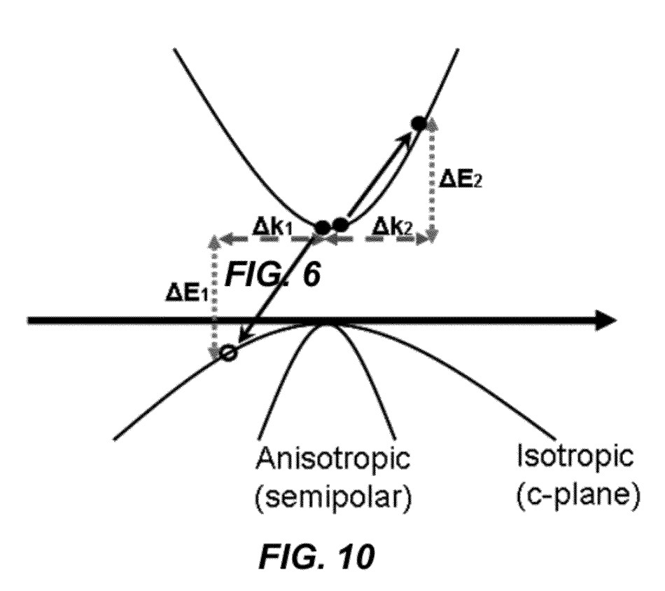

FIG. 10 is a diagram that illustrates the Auger recombination process for isotropically-strained structures (c-plane) and anisotropically-strained structures (semipolar), wherein Ak and AE are differences in momentum and energy, respectively, which should have same magnitudes but with opposite signs (Δk₁+Δk₂=0; ΔE₁+ΔE₂=0), in order to obey the momentum and energy conservations for the electrons and holes transitions in the conduction and valence bands, respectively. As shown in the figure, electron-electron-hole (EEH) direct Auger recombination can easily occur in the isotropically-strained structure because momentum and energy can be conserved (Δk₁=Δk₂, ΔE₁=ΔE₂) during the transition. On the other hand, EEH direct Auger recombination is suppressed in the anisotropically-strained structure due to the increased curvature of the valance band. In this case, the availability of final states that conserve both energy and momentum is limited and direct Auger recombination will be reduced. As a result, alloy scattering or phonon interactions must also participate in the transition for Auger recombination to occur. As discussed above, if alloy scattering is reduced in (20-2-1) QWs due to superior InGaN uniformity, indirect Auger recombination process should also be reduced. As a result, efficiency droop will be reduced on this semipolar plane.

Possible Modifications and Variations

The device 100 can be a semipolar or nonpolar device. The substrate 102 can be a semipolar or nonpolar III-nitride substrate. The device layers 104-112 can be semipolar or nonpolar layers, or have a semipolar or nonpolar orientation (e.g., layers 104-112 can be grown on or above each other and/or on or above the top/main/growth surface 130 of the substrate 102, wherein the top/main/growth surface 130 and top surface of the device layers (e.g., active layers) 130 is a semipolar (e.g., 20-2-1 or {20-2-1}) or nonpolar plane.

Variations in active region design, such as modifying the number of QWs, the thickness of the QWs, the QW and barrier compositions, and the active region doping level, are possible alternatives. The SL layers on the n-side and p-side may also be modified. For example, either of these layers may be omitted, contain a different number of periods, have alternative compositions or dopings, or be grown with different thicknesses than shown in the preferred embodiment. Other semipolar planes or substrates can be used.

Other variations include various possible epitaxial growth techniques (Molecular Beam Epitaxy (MBE), MOCVD, Vapor Phase Epitaxy, Hydride Vapor Phase Epitaxy (HVPE) etc.), different dry-etching techniques such as Inductively Coupled Plasma (ICP) etching, Reactive Ion Etching (RIE), Focused Ion beam (FIB) milling, Chemical Mechanical Planarization (CMP), and Chemically Assisted Ion Beam Etching (CAIBE). Formation of high light extraction structures, flip chip LEDs, vertical structure LEDs, thin GaN LEDs, chip-shaped LEDs, and advanced packaging methods, such as a suspended package, transparent stand package, etc., can also be used.

Nomenclature

The terms “(Al,Ga,In)N”, “GaN”, “InGaN”, “AlGaInN”, “Group-III nitride”, “III-nitride”, or “nitride”, and equivalents thereof, are intended to refer to any alloy composition of the (Al,Ga,In)N semiconductors having the formula AlₓGa_{y}In_{z}N where 0<x<1, 0<y<1, 0<z<1, and x+y+z=1. These terms are intended to be broadly construed to include respective nitrides of the single species, Al, Ga, and In, as well as binary and ternary compositions of such Group III metal species. Accordingly, it will be appreciated that the discussion of the invention hereinafter in reference to GaN and InGaN materials is applicable to the formation of various other (Al,Ga,In)N material species. Further, (Al,Ga,In)N materials within the scope of the invention may further include minor quantities of dopants and/or other impurity or inclusional materials.

Many (Al,Ga,In)N devices are grown along the polar c-plane of the crystal, although this results in an undesirable quantum-confined Stark effect (QCSE), due to the existence of strong piezoelectric and spontaneous polarizations. One approach to decreasing polarization effects in (Al,Ga,In)N devices is to grow the devices on nonpolar or semipolar planes of the crystal.

The term “nonpolar plane” includes the {11-20} planes, known collectively a-planes, and the {10-10} planes, known collectively as m-planes. Such planes contain equal numbers of Group-III (e.g., gallium) and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

### REFERENCES

The following references are incorporated by reference herein:

1. “High-Power Blue-Violet Semipolar (20-2-1) InGaN/GaN Light-Emitting Diodes with Low Efficiency Droop at 200 A/cm²”, by Yuji Zhao, Shinichi Tanaka, Chih-Chien Pan, Kenji Fujito, Daniel Feezell, James S. Speck, Steven P. DenBaars, and Shuji Nakamura, Applied Physics Express 4 (2011) 082104.

2. “Vertical Stand Transparent Light-Emitting Diode Architecture for High-Efficiency and High-Power Light Emitting Diodes,” by C. C. Pan, I. Koslow, J. Sonoda, H. Ohta, J. S. Ha, S. Nakamura, and S. P.DenBaars: Jpn. J. Appl. Phys. 49 (2010) 080210.

3. J. Matthews and A. Blakeslee, J. Cryst. Growth 32 265 (1976).

Conclusion

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A light emitting device, comprising:
a III-nitride based light emitting diode (LED) having a peak emission at a blue emission wavelength, wherein:
the LED is grown on a semipolar Gallium Nitride (GaN) substrate, and
the peak emission at the blue emission wavelength has a spectral width of less than 17 nanometers at a current density of at least 35 Amps per centimeter square (A/cm²).

2. The device of claim 1, wherein the LED is grown on a semipolar (20-2-1) GaN substrate.

3. The device of claim 1, wherein the LED is grown on a semipolar (20-21) GaN substrate.

4. The device of claim 1, wherein the blue emission wavelength is in a range of 430 nanometers (nm)-470 nm.

5. The device of claim 1, wherein an efficiency droop of the LED is less than 1% at the current density of at least 35 A/cm², less than 5% at the current density of at least 50 A/cm², less than 10% at the current density of at least 100 A/cm², or less than 15% at the current density of at least 200 A/cm².

6. The device of claim 2, further comprising:
an n-type III-nitride superlattice (n-SL) on or above the GaN substrate;
a III-nitride active region, on or above the n-SL, comprising one or more indium containing quantum wells (QWs) with barriers, the quantum wells having a QW number, a QW composition, and a QW thickness, the barriers having a barrier composition, barrier thickness, and barrier doping; and
a p-type III-nitride superlattice (p-SL) on or above the active region;
wherein:
the n-SL comprises a number of periods, an SL doping, an SL composition, and layers each having a layer thickness, and
the QW number, the QW composition, the QW thickness, the barrier composition, the barrier thickness, the barrier doping, the number of periods, the SL doping, the SL composition, the layer thickness are such that:
the peak emission is at the blue emission wavelength, and
the peak emission at the blue emission wavelength has a spectral width of less than 17 nanometers when the LED is driven with a current density of at least 35 Amps per centimeter square (A/cm²).

7. The device structure of claim 1, further comprising:
an n-type GaN layer on or above a semi-polar plane of the substrate, wherein:
the substrate is a semi-polar GaN substrate having a roughened backside and the roughened backside extracts light from the light emitting device, and
the n-SL comprises alternating InGaN and GaN layers on or above the n-type GaN layer;
an active region, comprising InGaN multi quantum wells (MQWs) with GaN barriers, on or above the n-SL;
a p-type superlattice (p-SL) on or above the active region, comprising alternating AlGaN and GaN layers;
a p-type GaN layer on or above the p-SL;
a p-type transparent conductive layer on or above the p-type GaN layer;
a p-type pad on or above the p-type transparent conductive layer;
an n-type contact to the n-type GaN layer;
a Zinc Oxide (ZnO) submount attached to the roughened backside of the semipolar GaN substrate;
a header attached to an end of the ZnO submount; and
an encapsulant encapsulating the LED, wherein an active area of the device structure that is an LED is 0.1 mm² or less.

8. A method of fabricating a light emitting device, comprising:
growing a III-nitride based light emitting diode (LED) on a semipolar Gallium Nitride (GaN) substrate, wherein:
the LED has a peak emission at a blue emission wavelength, and
the peak emission at the blue emission wavelength has a spectral width of less than 17 nanometers at a current density of at least 35 Amps per centimeter square (A/cm²).

9. The method of claim 8, wherein the LED is grown on a semipolar (20-2-1) GaN substrate.

10. The method of claim 8, wherein the LED is grown on a semipolar (20-21) GaN substrate.

11. The method of claim 8, wherein the blue emission wavelength is 430 nanometers (nm) and 470 nm.

12. The method of claim 8, wherein an efficiency droop of the LED is less than 1% at the current density of at least 35 A/cm², less than 5% at the current density of at least 50 A/cm², less than 10% at the current density of at least 100 A/cm², or less than 15% at the current density of at least 200 A/cm².

13. The method of claim 8, wherein growing the LED further comprises:
growing a III-nitride n-type superlattice (n-SL) on or above the GaN substrate;
growing a III-nitride active region, on or above the n-SL, comprising one or more indium containing quantum wells (QWs) with barriers, the quantum wells having a QW number, a QW composition, and a QW thickness, the barriers having a barrier composition, barrier thickness, and barrier doping;
growing a III-nitride p-type superlattice (p-SL) on or above the active region;
wherein:
the n-SL comprises a number of periods, an SL doping, an SL composition, and layers each having a layer thickness, and
the QW number, the QW composition, the QW thickness, the barrier composition, the barrier thickness, the barrier doping, the number of periods, the SL doping, the SL composition, the layer thickness are such that:
the peak emission is at the blue emission wavelength, and
the peak emission at the blue emission wavelength has a spectral width of less than 17 nanometers when the LED is driven with a current density of at least 35 Amps per centimeter square (A/cm²).

14. A light emitting device, comprising:
a III-nitride based light emitting diode (LED) having a peak emission at a blue emission wavelength, wherein:
the LED is grown on a bulk semipolar or nonpolar Gallium Nitride (GaN) substrate, and
an efficiency droop is lower than a III-nitride based LED grown on a polar GaN substrate having a similar Indium (In) composition and operating at a similar current density.

15. The device of claim 14, wherein the semipolar substrate is a semipolar (20-2-1) substrate.

16. The device of claim 14, wherein a full width at half maximum (FWHM) of an emission spectrum of the LED is lower than that of a III-nitride based LED grown on a polar GaN substrate having a similar indium composition and operating at a similar current density.
